(19) United States
(12) Patent Application Publication
(10) Pub. No.: US 2025/0331207 A1
(43) Pub. Date: Oct. 23, 2025

(54) SILICON-ON-INSULATOR (SOI) POWER DEVICE WITH INTRODUCED FIXED CHARGES

(71) Applicant: SOOCHOW UNIVERSITY, Suzhou (CN)

(72) Inventors: Mingxiang WANG, Suzhou (CN); Fengchi WANG, Suzhou (CN); Dongli ZHANG, Suzhou (CN); Huaisheng WANG, Suzhou (CN)

(73) Assignee: SOOCHOW UNIVERSITY, Suzhou (CN)

(21) Appl. No.: 19/023,527

(22) Filed: Jan. 16, 2025

(30) Foreign Application Priority Data
Apr. 22, 2024 (CN) 202410485095.4

(51) Int. Cl. H10D 12/00; H10D 62/13; H10D 62/17

(52) U.S. Cl. CPC H10D 12/421; H10D 62/142; H10D 62/145; H10D 62/151; H10D 62/393

(57) ABSTRACT

A silicon-on-insulator (SOI) power device with introduced fixed charges is provided. The SOI power device is a shorted-anode—lateral insulated gate bipolar transistor (SA-LIGBT) or separated shorted-anode—lateral insulated gate bipolar transistor (SSA-LIGBT) structure, and includes a semiconductor substrate, a dielectric buried layer, and a semiconductor active layer stacked in sequence, where a first charge layer is provided between the dielectric buried layer and the semiconductor active layer, and/or a second charge layer is provided between a field oxide layer and the semiconductor active layer; and the charge layer carries continuously and uniformly distributed positive charges. The snapback present in the output characteristics of the traditional SA-LIGBT or SSA-LIGBT is addressed. By inserting the fixed charges between the dielectric buried layer and the semiconductor active layer, the SOI power device reduces the voltage of the snapback effect and significantly suppresses the occurrence of the snapback phenomenon.

CROSS REFERENCE TO THE RELATED APPLICATIONS

This application is based upon and claims priority to Chinese Patent Application No. 202410485095.4, filed on Apr. 22, 2024, the entire contents of which are incorporated herein by reference.

### TECHNICAL FIELD

The present disclosure belongs to the technical field of power semiconductors, and in particular relates to a silicon-on-insulator (SOI) power device with introduced fixed charges.

### BACKGROUND

Insulated gate bipolar transistor (IGBT) devices are widely used as a representative of silicon-on-insulator (SOI) power devices with beneficial characteristics such as a high working speed, a high integration level, and good insulation performance. Primary lateral insulated gate bipolar transistor (LIGBT) devices perform poorly in terms of turn-off characteristics, and a shorted-anode lateral insulated gate bipolar transistor (SA-LIGBT) can be added to help the device quickly turn off. But this will cause a new problem, which is the snapback phenomenon in the output characteristic curve.

### SUMMARY

In response to the shortcomings of the prior art, the present disclosure provides a silicon-on-insulator (SOI) power device with introduced fixed charges, to solve the snapback in the output characteristics of traditional SOI power devices.

The present disclosure achieves the above technical objective through the following technical solution:

A SOI power device with introduced fixed charges includes a semiconductor substrate, a dielectric buried layer, and a semiconductor active layer stacked in sequence, where a first charge layer is provided between the dielectric buried layer and the semiconductor active layer, and/or a second charge layer is provided between a field oxide layer and the semiconductor active layer; and positive charges are carried in the first charge layer and the second charge layer.

Further, the SOI power device is a separated shorted-anode-lateral insulated gate bipolar transistor (SSA-LIGBT) structure.

Further, the first charge layer and the second charge layer are configured to suppress a snapback phenomenon in an output characteristic curve.

Further, on a top of the semiconductor active layer, one side is provided with a P-body region and another side is provided with an N-buffer and a drain short-circuit N+ region; an upper layer of the P-body region includes a source P+ region and a source N+ region arranged in sequence along a lateral direction; the source N+ region and the P-body region are jointly covered by a gate; the N-buffer is provided with a drain P+ region; and the drain P+ region and the drain short-circuit N+ region are provided with a drain.

Further, a range of the first charge layer is defined by a starting point located below a position from the source P+ region to a drift region and an ending point located below a position from the drift region to an isolation region.

Further, the range of the first charge layer starts from a position below the source P+ region to a position below the N-buffer, and the ending point of the first charge layer at least reaches a position below the drain P+ region.

Further, the SOI power device is a shorted-anode-lateral insulated gate bipolar transistor (SA-LIGBT) structure.

Further, the first charge layer and the second charge layer are formed of a dielectric material.

Further, the first charge layer and the second charge layer inject positive ions into an upper surface of the dielectric buried layer through ion implantation.

Further, the positive ions are positive cesium ions, positive boron ions, or positive ions formed by another group I or III element.

Further, the first charge layer and the second charge layer have a surface charge density of greater than 1×10¹²/cm²; and the charges in the first charge layer and the second charge layer are distributed continuously and uniformly along the first charge layer and the second charge layer.

Further, the first charge layer has a surface charge density of 1.3×10¹³/cm².

Further, the second charge layer has a surface charge density of 8×10¹² to 9×10¹²/cm².

Further, the first charge layer and the second charge layer each have a surface charge density of 5×10¹²/cm².

Further, the semiconductor active layer is made of silicon (Si), silicon carbide (SIC), gallium arsenide (GaAs), or gallium nitride (GaN), while the dielectric buried layer is made of silicon dioxide (SiO₂) or another low dielectric constant (K) material.

The present disclosure has the following advantages:

(1) The present disclosure provides a SOI power device with introduced fixed charges. To address the snapback present in the output characteristics of the traditional SSA-LIGBT or SA-LIGBT, fixed charges are between the dielectric buried layer and the semiconductor active layer to reduce the voltage of the snapback phenomenon and significantly suppress its occurrence.

(2) The present disclosure further provides the range region of the charge layer. When the introduced charge boundary is located below the drain P+ region but not exceeding the N-buffer, the snapback suppression ability is the strongest.

(3) The charge layer in the present disclosure can be implemented through ion implantation, which is fully compatible with conventional complementary metal-oxide-semiconductor transistor (CMOS)/SOI processes and is simple and reliable in process implementation.

### BRIEF DESCRIPTION OF THE DRAWINGS

FIG. 1 is a structural diagram of a silicon-on-insulator (SOI) power device based on a separated shorted-anode-lateral insulated gate bipolar transistor (SSA-LIGBT) in Embodiment 1 of the present disclosure;

FIG. 2A is an electron current flow diagram of a conventional structure without introduced charges;

FIG. 2B is an electron current flow diagram of the present disclosure after introducing charges;

FIG. 3A is an output characteristic curve of the SOI device in the present disclosure;

FIG. 3B is an output characteristic curve of the SOI device changing with a charge quantity in a charge layer in the present disclosure;

FIG. 4A is a schematic structural diagram in case an ending point of an introduced charge range is located before a drain P+ region;

FIG. 4B is a schematic structural diagram in case the ending point of the introduced charge range is located after an N-buffer;

FIG. 5A is an output characteristic curve comparison diagram in case the charge range is located before the drain P+ region;

FIG. 5B is an output characteristic curve comparison diagram in case the charge range is located after the N-buffer;

FIG. 6A is a curve comparison in case a fixed charge quantity increases when the charge range is located before the drain P+ region;

FIG. 6B is a curve comparison in case the fixed charge quantity increases when the charge range is located after the N-buffer;

FIG. 7A is a complete output characteristic curve comparison in case the fixed charge quantity increases when the charge range is located before the drain P+ region;

FIG. 7B is a complete output characteristic curve comparison in case the fixed charge quantity increases when the charge range is located after the N-buffer;

FIG. 8 is a schematic structural diagram in case a starting point of the introduced charge range is located after a right side of a P-body region;

FIG. 9A is an output characteristic curve diagram in case the charges start after the P-body region and ends in an optimal region;

FIG. 9B is an output characteristic curve diagram in case the charges start after the P-body region and ends before the drain P+ region;

FIG. 9C is an output characteristic curve diagram in case the charges start after the P-body region and ends after the N-buffer;

FIG. 10A is a curve comparison in case the fixed charge quantity increases when the charges start after the P-body region and ends in the optimal region;

FIG. 10B is a curve comparison in case the fixed charge quantity increases when the charges start after the P-body region and ends before the drain P+ region;

FIG. 10C is a curve comparison in case the fixed charge quantity increases when the charges start after the P-body region and ends after the N-buffer;

FIG. 11A is a complete output characteristic curve comparison in case the charges start after the P-body region and ends in an optimal region;

FIG. 11B is a complete output characteristic curve comparison in case the charges start after the P-body region and ends before the drain P+ region;

FIG. 11C is a complete output characteristic curve comparison in case the charges start after the P-body region and ends after the N-buffer;

FIG. 12A is a schematic structural diagram of a SOI power device with only a second charge layer in Embodiment 2;

FIG. 12B is a schematic structural diagram of a SOI power device with both first and second charge layers in Embodiment 2;

FIG. 13A is an output characteristic curve in case only the second charge layer is provided;

FIG. 13B is an output characteristic curve in case the first and second charge layers are simultaneously provided;

FIG. 14A is an output characteristic curve in case the second charge layer starts in the right of a left boundary of a field oxide layer;

FIG. 14B is an output characteristic curve in case the second charge layer ends in the left of a right boundary of the field oxide layer;

FIG. 15 is a structural diagram of a SOI power device based on a shorted-anode-lateral insulated gate bipolar transistor (SA-LIGBT) in Embodiment 3 of the present disclosure; and

FIG. 16 is an output characteristic curve of the structure shown in FIG. 15.

### REFERENCE NUMERALS

1. semiconductor substrate; 2. dielectric buried layer; 3. P-body region; 4. source P+ region;
5. source N+ region; 6. gate; 7. semiconductor active layer; 8. drain P+ region;
9. N-buffer; 10. drain short-circuit N+ region; 11. drain; 12. first charge layer;
13. field oxide layer; and 14. second charge layer.

### DETAILED DESCRIPTION OF THE EMBODIMENTS

The embodiments of the present disclosure are described below in detail. Examples of the embodiments are shown in the drawings. The same or similar numerals represent the same or similar elements or elements having the same or similar functions throughout the specification. The embodiments described below with reference to the drawings are illustrative for explaining the present disclosure and are not to be construed as limiting the present disclosure.

### Embodiment 1

### I. Structural Description

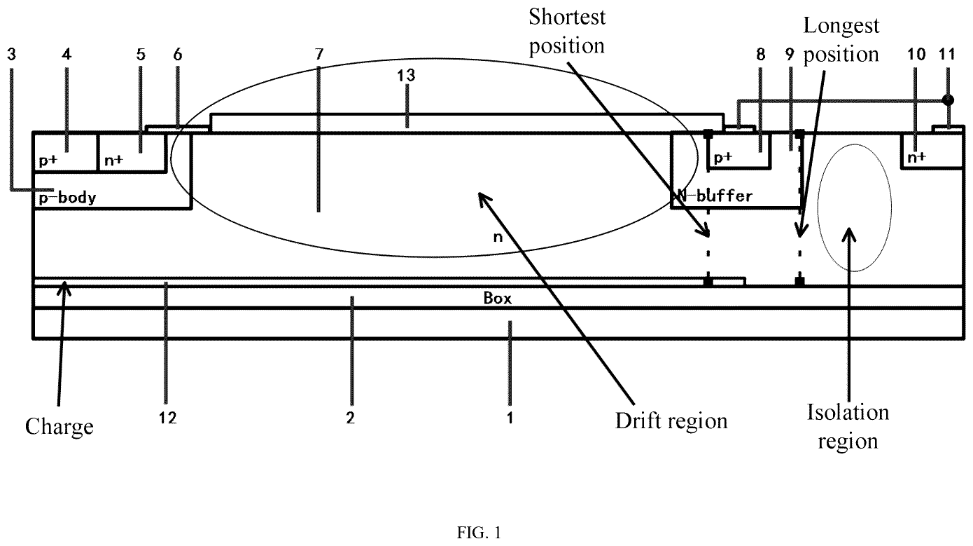

As shown in FIG. 1, as a separated shorted-anode-lateral insulated gate bipolar transistor (SSA-LIGBT) structure, a silicon-on-insulator (SOI) power device includes a semiconductor substrate 1, a dielectric buried layer 2, and a semiconductor active layer 7 stacked in sequence from bottom to top. The semiconductor active layer 7 can be made of a material such as silicon (Si), silicon carbide (SiC), gallium arsenide (GaAs), or gallium nitride (GaN), while the dielectric buried layer 2 can be made of silicon dioxide (SiO₂) or another low dielectric constant (K) material.

On a top of the semiconductor active layer 7, one side is provided with a P-body region 3 and another side is provided with an N-buffer 9 and a drain short-circuit N+ region 10. An upper layer of the P-body region 3 includes a source P+ region 4 and a source N+ region 5 arranged in sequence along a lateral direction. The source N+ region 5 and the P-body region 3 are jointly covered by a gate 6. The N-buffer 9 is provided with a drain P+ region 8. The drain P+ region 8 and the drain short-circuit N+ region 10 are provided with a drain 11.

A first charge layer 12 is provided at a boundary between the dielectric buried layer 2 and the semiconductor active layer 7. The first charge layer 12 includes a high concentration of fixed charges. A range of the first charge layer 12 starts from below the source P+ region 4 and ends below the N-buffer 9. An ending point of the first charge layer 12 must reach at least below the drain P+ region 8 but not after the entire N-buffer 9. The first charge layer 12 is formed from a dielectric material and has a positive charge polarity. Specifically, positive ions can be injected into an upper surface of the dielectric buried layer 2 through ion implantation. The injected positive ions can be positive cesium ions, positive boron ions, or positive ions formed by another group I or III element such as iodine. The first charge layer 12 has a surface charge density of greater than 1×10¹²/cm². The charge distribution in each injection region is uniform, and each injection region is closely connected to ensure a continuous and uniform distribution of fixed charges along the first charge layer 12.

### II. Performance Testing

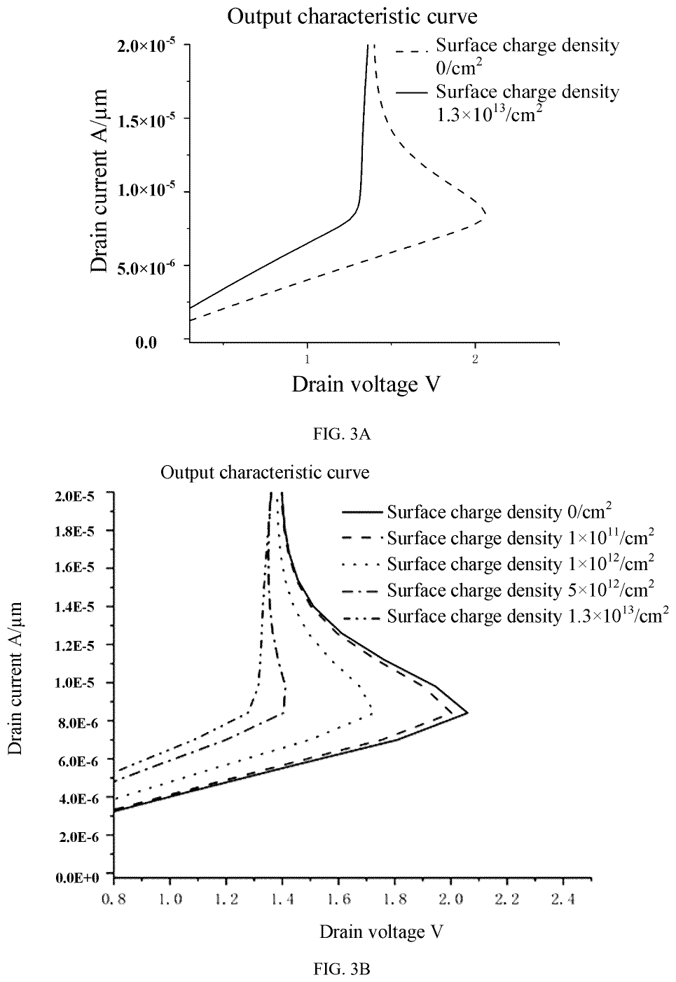

As shown in FIG. 3A, the dashed line in the figure represents an output characteristic curve of a conventional SSA-LIGBT, which exhibits an obvious snapback phenomenon. The solid line in the figure (where the introduced fixed charges have a surface charge density of 1.3×10¹³/cm²) represents an output characteristic curve of the present disclosure after introducing positive charges, indicating significant suppression of the snapback phenomenon. In the present disclosure, the snapback phenomenon is effectively suppressed by introducing positive charges (the first charge layer 12) between the dielectric buried layer 2 and the semiconductor active layer 7. As shown in FIG. 3B, the snapback phenomenon in the output characteristic curve gradually decreases with the increase of the charge quantity in the first charge layer 12, indicating that the ability to suppress the snapback phenomenon is positively correlated with the charge quantity in the charge layer. On the other hand, even if a small quantity of charges is introduced, it can still have a certain suppression effect on the snapback phenomenon.

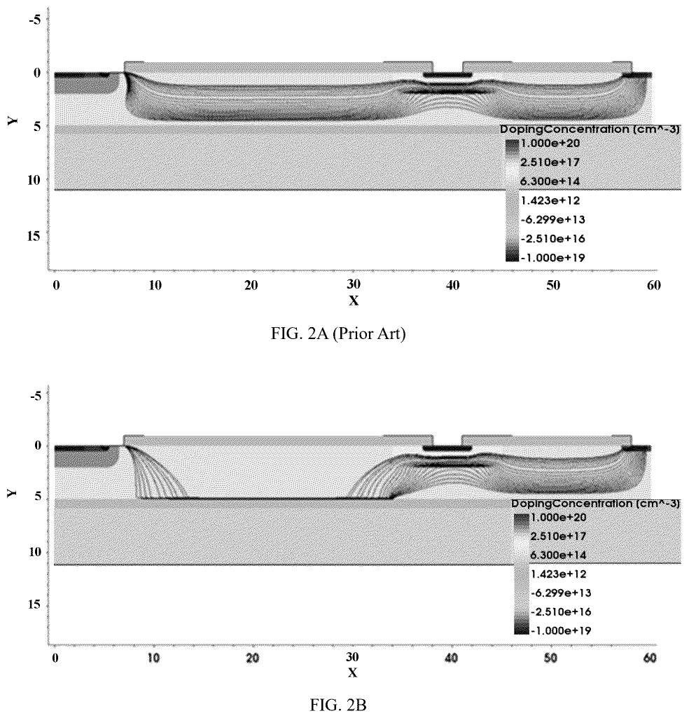

FIG. 2A shows an electron current flow diagram of the conventional SSA-LIGBT, and FIG. 2B shows an electron current flow diagram of the present disclosure after introducing fixed charges. After the addition of the charges, the speed of the device's transition from unipolar to bipolar conduction is accelerated, and the voltage required for snapback is reduced. After the positive charges are added into the SSA-LIGBT, when an insulated gate induced channel is turned on, the surface of the dielectric buried layer 2 attracts electron charges, resulting in an increase in the electron current density during unipolar conduction. In this way, the electron carrier concentration in the drain P+ region 8 and the buffer layer (N-buffer 9) increases, and the drain PN structure can quickly reach the conduction voltage drop, causing conduction to occur.

### III. Optimal range validation

### 1. Ending Point of the Charge Layer

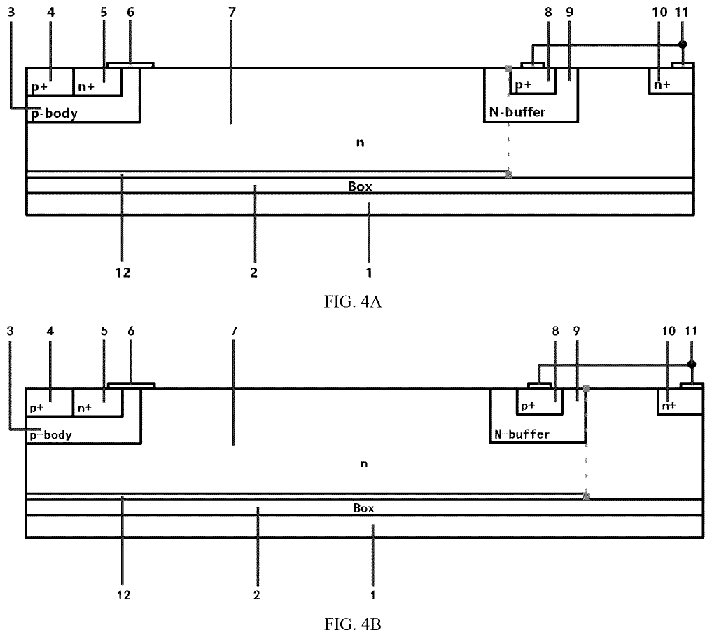

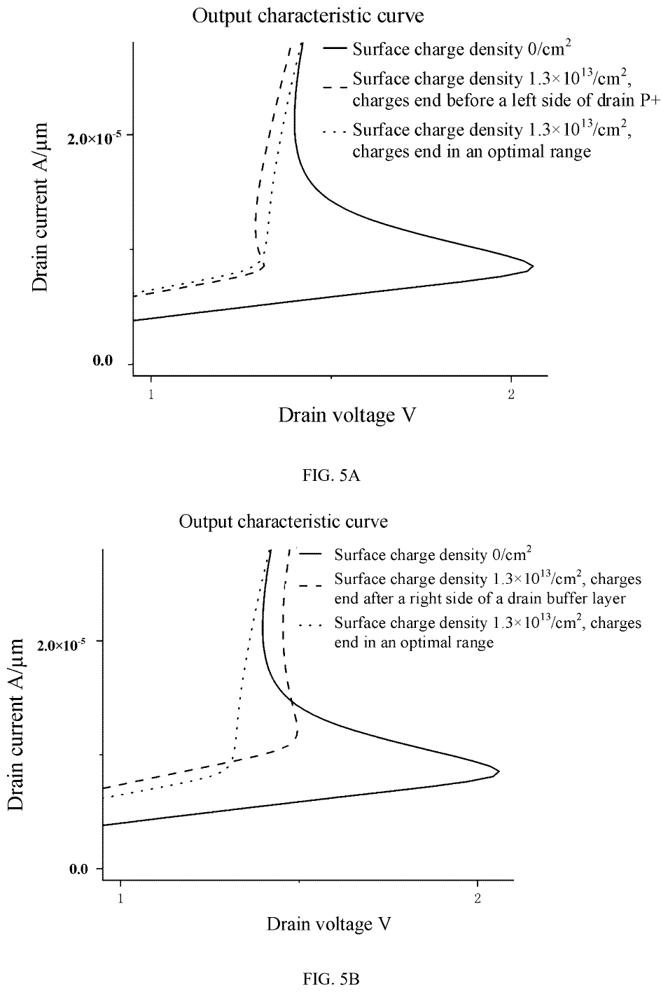

The elimination of the snapback phenomenon mainly relies on the large accumulation of electron carriers in the drain P+ region 8 to quickly conduct the drain PN junction. Therefore, the position where the charges are introduced should not be too large or too small. As shown in FIG. 4A, the introduced charge range is located before the drain P+ region 8, and the corresponding output characteristic curve is shown in FIG. 5A. As shown in FIG. 4B, the charge range is located after the drain N-buffer 9, and the corresponding output characteristic curve is shown in FIG. 5B. FIG. 5A and FIG. 5B indicate that when the introduced charge range ends before the drain P+ region 8, the electron carrier concentration in the drain P+ region 8 is lower than that in case of ending in the optimal region as the concentration of the added charges is lower than the fixed charge concentration in case of ending in the optimal region. Therefore, compared to the case of ending in the optimal region, the drain PN junction cannot conduct quickly, weakening the ability to suppress the snapback phenomenon. When the charge range exceeds the drain N-buffer 9, since the SSA-LIGBT increases the resistance of electrons from the drain P+ region to the drain N+ region by increasing the isolation region, introducing charges into the isolation region increases the electron carrier concentration, thereby reducing the resistance in the isolation region. This also weakens the ability to suppress the snapback phenomenon.

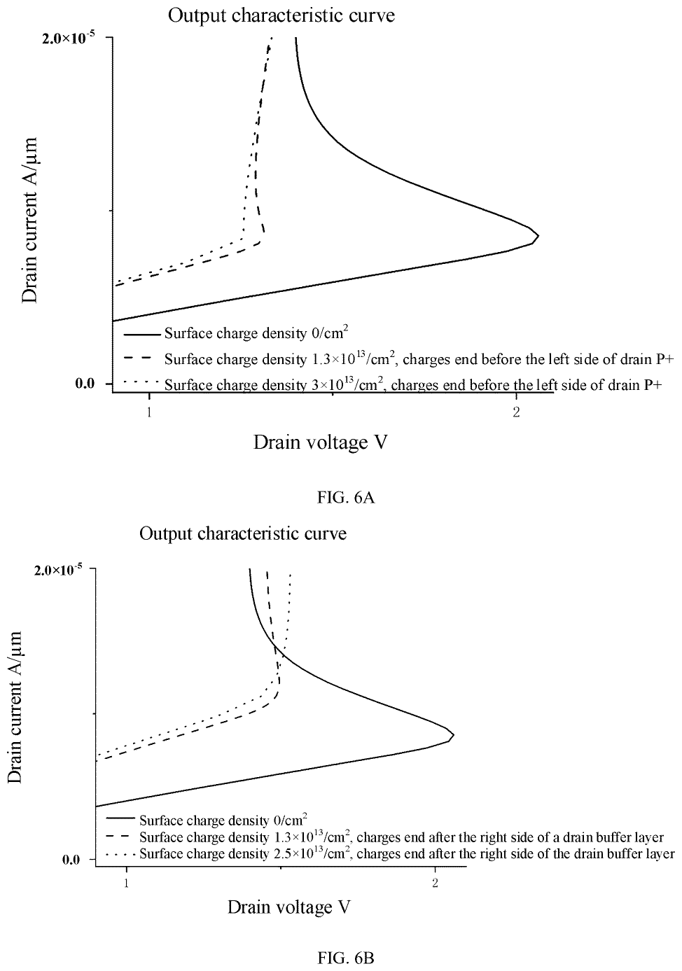

As shown in FIG. 6A and FIG. 6B, when the ending point of the first charge layer 12 is not within the optimal range required by the present disclosure, a higher quantity of fixed charges needs to be introduced to improve the output characteristic curve. As shown in FIG. 6A, before the drain P+ region 8, the surface charge density in the first charge layer 12 increases from 1.3×10¹³/cm² to 3×10¹³/cm², and the snapback phenomenon in the output curve is suppressed to some extent. As shown in FIG. 6B, after the N-buffer 9, the surface charge density in the first charge layer 12 increases from 1.3×10¹³/cm² to 2.5×10¹³/cm², and the snapback phenomenon in the output curve is suppressed to some extent.

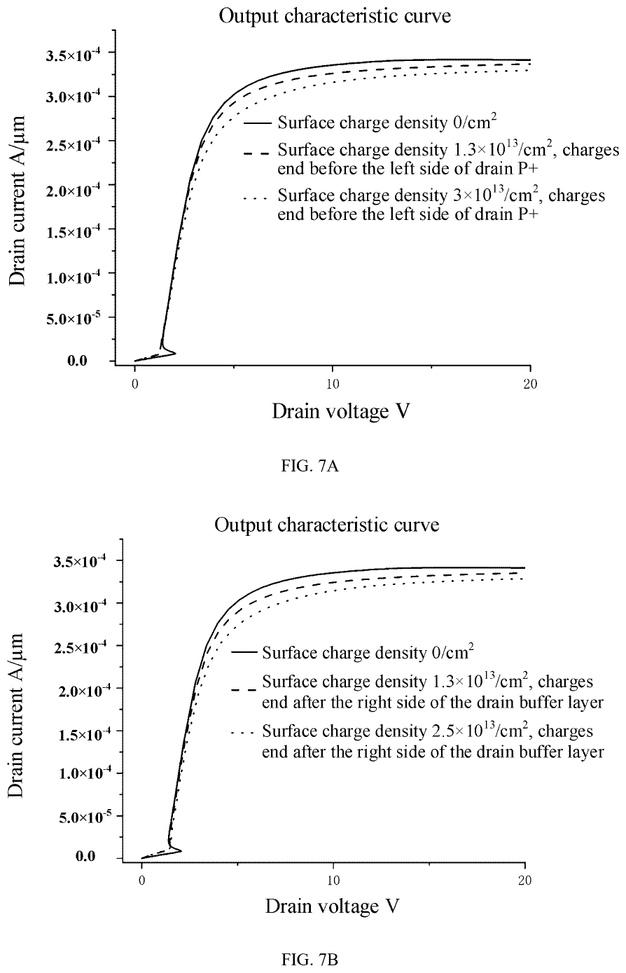

However, introducing excessive fixed charges will result in an increase in the output resistance, as shown in FIG. 7A and FIG. 7B.

### 2. Starting Point of the Charge Layer

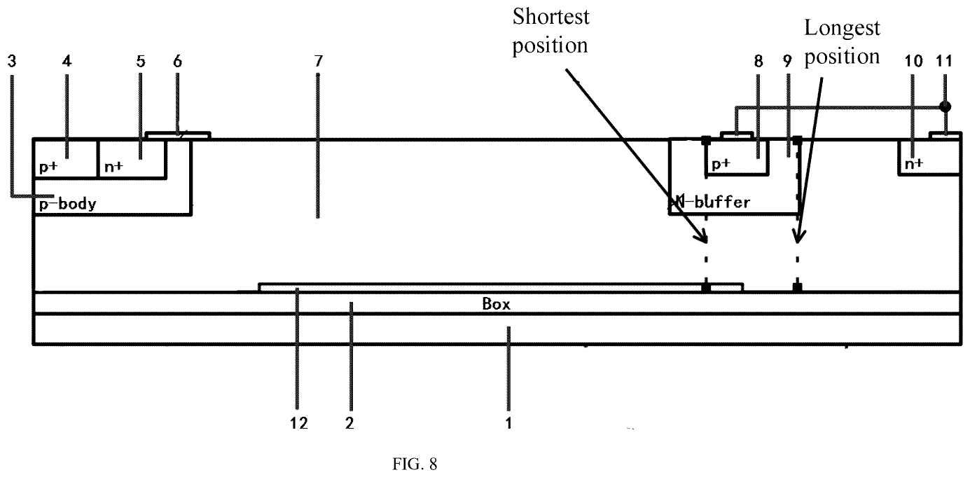

As shown in FIG. 8, the starting point of the charge layer is located after the P-body region 3 (i.e. below the drift region). In this case, three substructures can be divided, namely (1) the ending point is located within the optimal region specified by the present disclosure (between the “shortest position” and the “longest position” in the figure), (2) the ending point is located before the drain P+ region 8 (in the left of the “shortest position” in the figure), and (3) the ending point is located after the N-buffer 9 (in the right of the “longest position” in the figure).

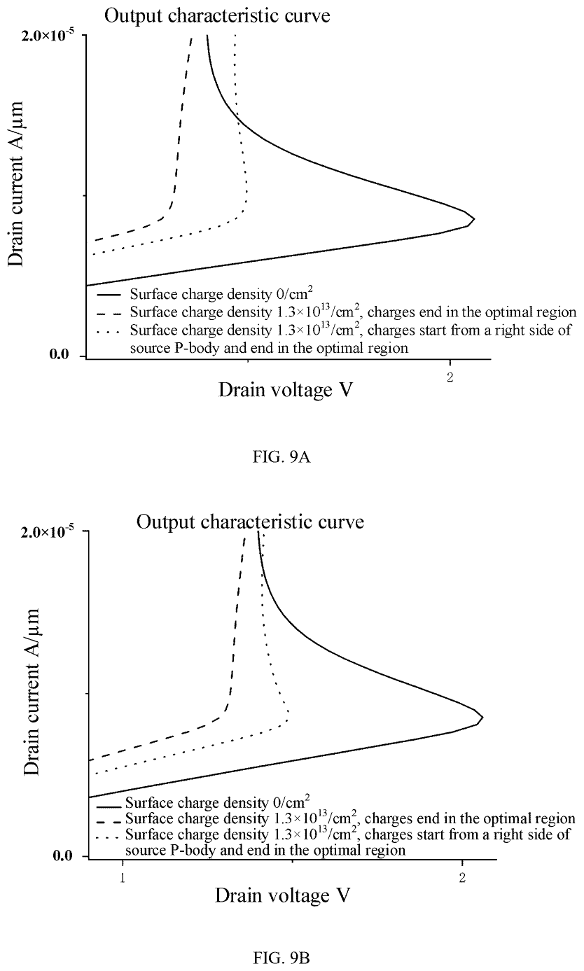

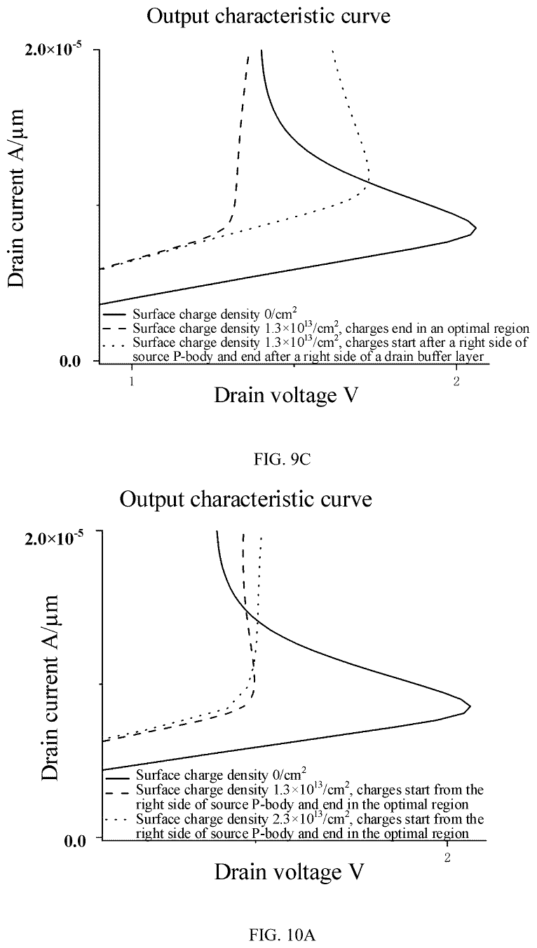

The output characteristic curves of the three structures are shown in FIG. 9A, FIG. 9B, and FIG. 9C, respectively. It can be seen that when the starting point of the first charge layer 12 is shifted to the right to a position after the P-body region 3, although it can also have a certain snapback suppression effect, the snapback suppression effect is reduced compared to the position below the source P+ region 4 required by the present disclosure.

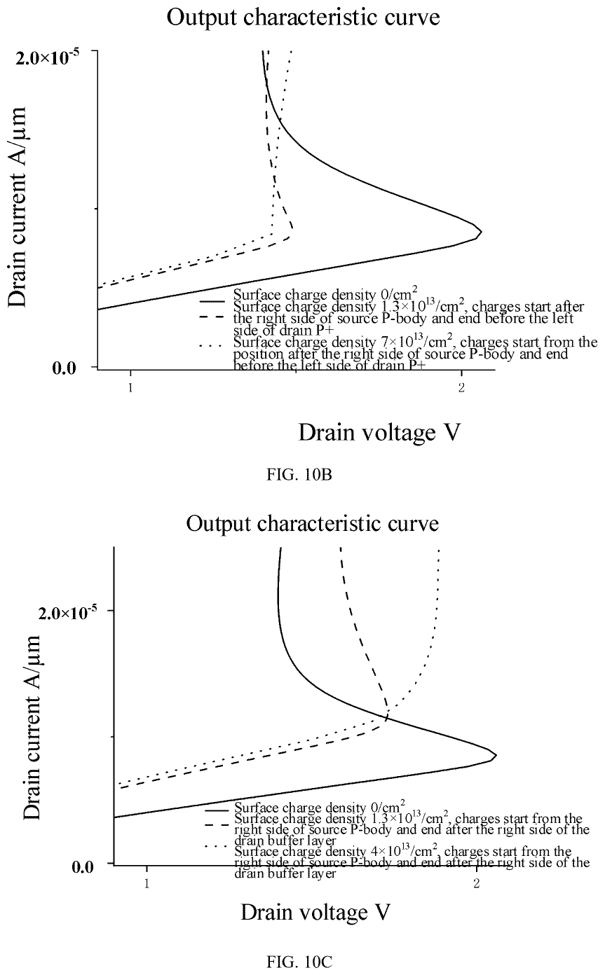

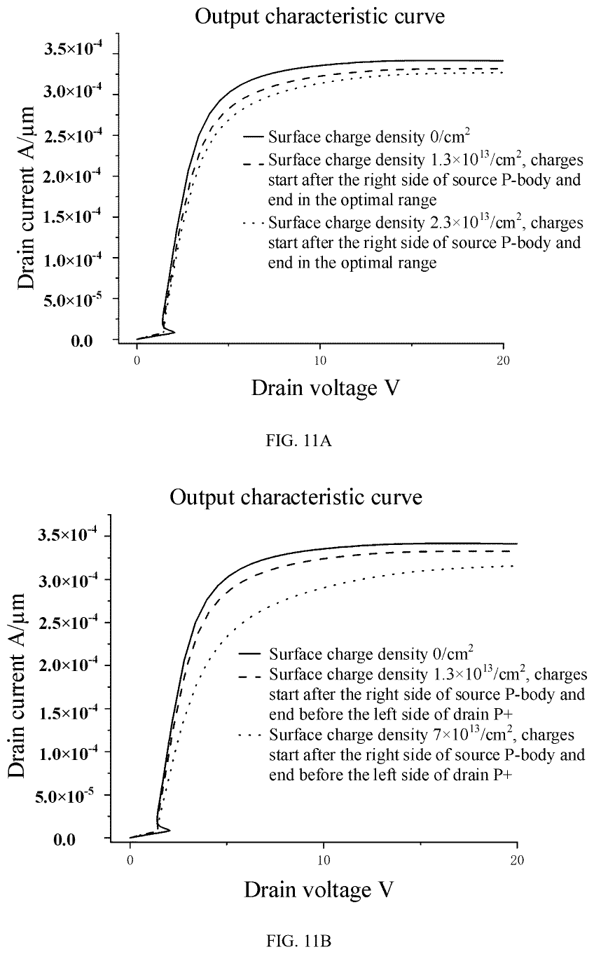

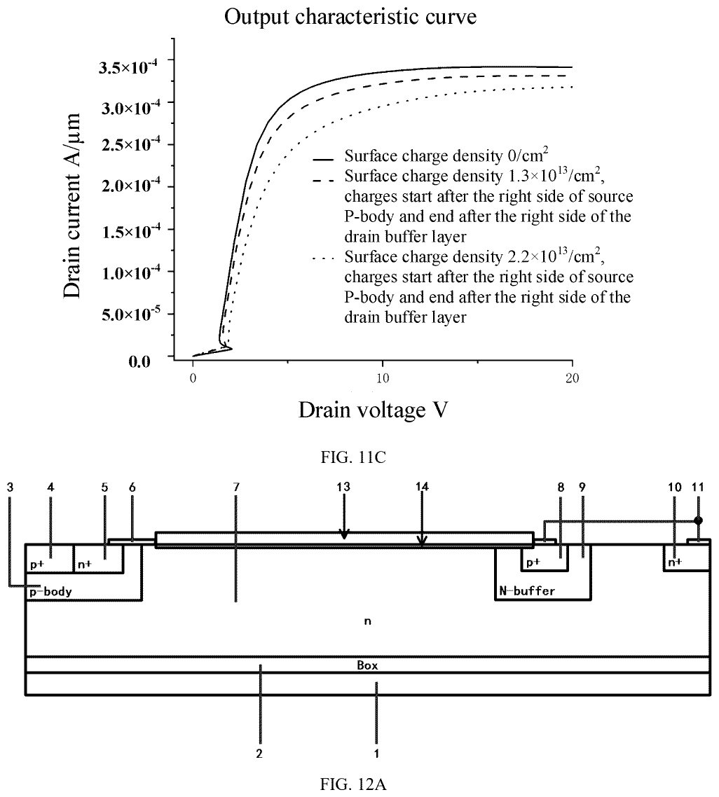

Similarly, all these three structures can enhance the snapback suppression effect by increasing the charge quantity, and the corresponding test results are shown in FIG. 10A, FIG. 10B, and FIG. 10C. However, introducing excessive fixed charges can lead to an increase in the output resistance, as shown in the test results in FIG. 11A, FIG. 11B, and FIG. 11C.

### Embodiment 2

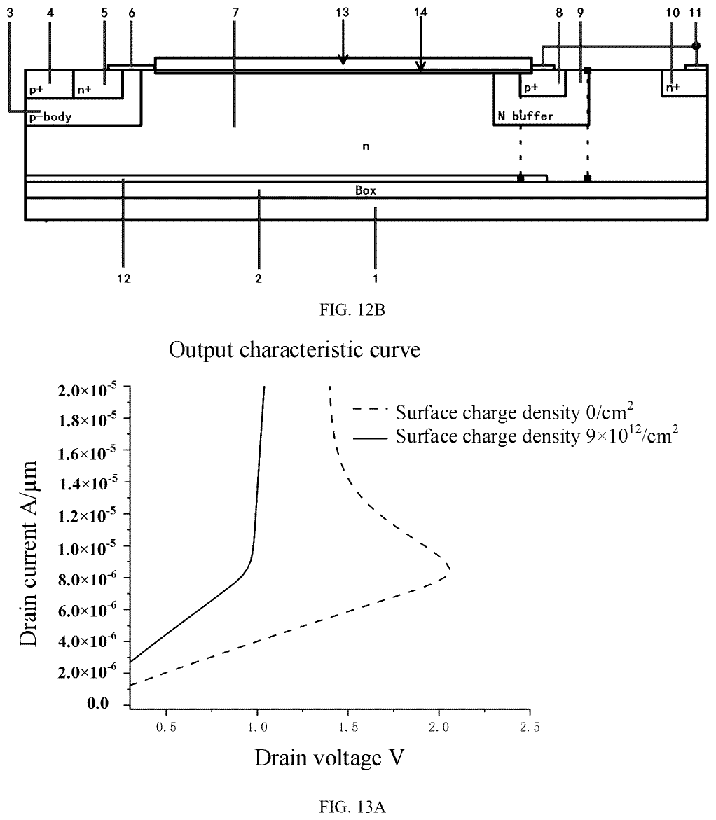

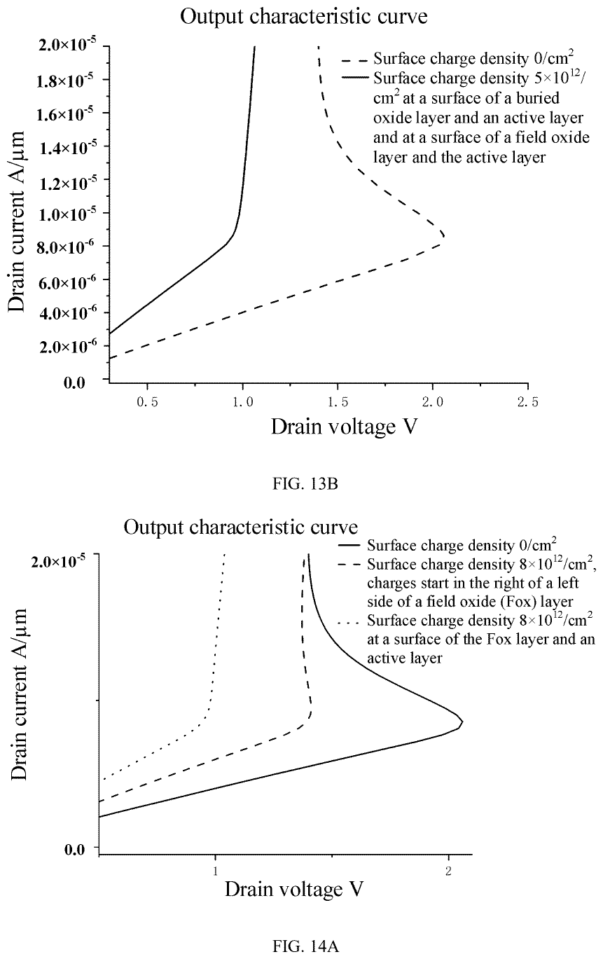

A charge layer is provided between the dielectric buried layer 2 and the semiconductor active layer. In addition, as shown in FIG. 12A, a second charge layer 14 is provided between a field oxide layer 13 and the semiconductor active layer 7. A length range of the second charge layer 14 is the same as that of the field oxide layer 13, and the corresponding output characteristic curve is shown in FIG. 13A. The second charge layer 14 carries positive charges with a surface charge density of 9×10¹²/cm², which can significantly suppress the snapback phenomenon.

Of course, as shown in FIG. 12B, the first charge layer 12 and the second charge layer 14 can be provided simultaneously, and the corresponding output characteristic curve is shown in FIG. 13B. The two charge layers both include positive charges with a surface charge density of 5×10¹²C/cm², which can significantly suppress the snapback phenomenon.

To further investigate the effect of the starting and ending range of the second charge layer 14 on suppressing the snapback phenomenon, the following comparative tests are conducted.

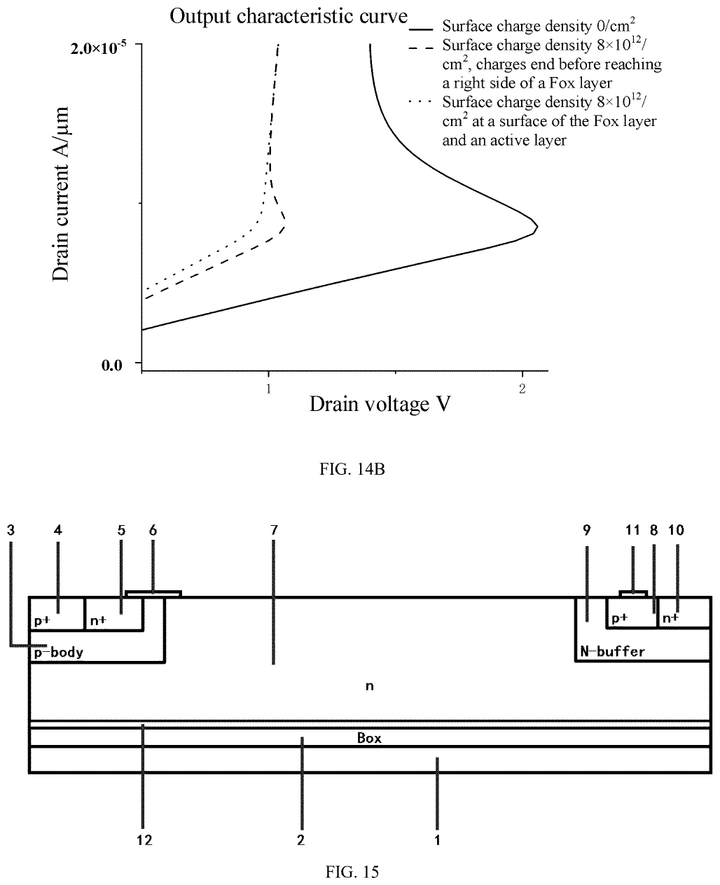

As shown in FIG. 14A, the starting point of the second charge layer 14 shown in FIG. 12A is shifted to the right (i.e., the charge starting position is biased towards the right of the left end of the field oxide layer 13), while the ending point remains unchanged, with a surface charge density of 8×10¹²/cm². In contrast, the suppression effect decreases.

As shown in FIG. 14B, the ending point of the second charge layer 14 shown in FIG. 12A is shifted to the left (i.e., the charge ending position is biased towards the left of the right end of the field oxide layer 13), while the starting point remains unchanged. Similarly, the suppression effect decreases.

Therefore, the best effect is achieved when the entire lower layer of the field oxide layer 13 is filled with a charge layer.

### Embodiment 3

In the present disclosure, the technical solution of eliminating snapback by introducing fixed charges is also applicable to SA-LIGBT structures.

FIG. 15 shows a SOI power device based on a SA-LIGBT in the present disclosure. Similar to that in Embodiment 1, a charge layer 12 is provided between the dielectric buried layer 2 and the semiconductor active layer 7. The charge layer 12 carries positive charges with a surface charge density of 1.3×10¹³/cm². The range of the charge layer 12 extends from below the source P+ region 4 to below the drain short-circuit N+ region 10.

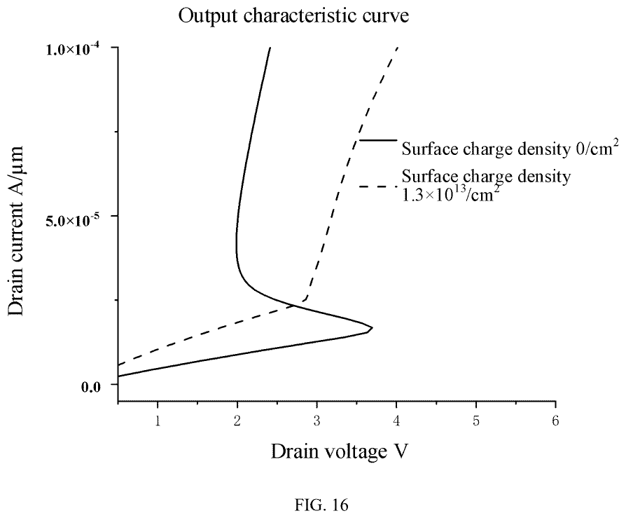

The corresponding output characteristic curve is shown in FIG. 16. For the SA-LIGBT structure, introducing fixed charges between the dielectric buried layer 2 and the semiconductor active layer 7 can effectively eliminate the snapback phenomenon.

It should be understood that in the description of the present disclosure, terms such as “upper”, “lower”, “front”, “rear”, “left”, “right” “vertical”, “horizontal”, “top”, “bottom”, “inside” and “outside” indicate the orientations or positional relationships based on the drawings, and these terms are merely intended to facilitate and simplify the description of the present disclosure, rather than to indicate or imply that the mentioned apparatus or element must have a specific orientation or must be constructed and operated in a specific orientation, and thus cannot be construed as limitations to the present disclosure.

The present disclosure is not limited to the above implementations. Any obvious improvements, substitutions, or modifications made by those skilled in the art without departing from the essence of the present disclosure should fall within the protection scope of the present disclosure.

What is claimed is:

1. A silicon-on-insulator (SOI) power device with introduced fixed charges, comprising a semiconductor substrate, a dielectric buried layer, and a semiconductor active layer stacked in sequence, wherein a first charge layer is provided between the dielectric buried layer and the semiconductor active layer, and/or a second charge layer is provided between a field oxide layer and the semiconductor active layer; and positive charges are carried in the first charge layer and the second charge layer.

2. The SOI power device with the introduced fixed charges according to claim 1, wherein the SOI power device is a separated shorted-anode-lateral insulated gate bipolar transistor structure or a shorted-anode-lateral insulated gate bipolar transistor structure; and the first charge layer and the second charge layer are configured to suppress a snapback phenomenon in an output characteristic curve.

3. The SOI power device with the introduced fixed charges according to claim 2, wherein on a top of the semiconductor active layer, a first side is provided with a P-body region and a second side is provided with an N-buffer and a drain short-circuit N+ region; an upper layer of the P-body region comprises a source P+ region and a source N+ region arranged in sequence along a lateral direction; the source N+ region and the P-body region are jointly covered by a gate; the N-buffer is provided with a drain P+ region; and the drain P+ region and the drain short-circuit N+ region are provided with a drain.

4. The SOI power device with the introduced fixed charges according to claim 3, wherein a range of the first charge layer is defined by a starting point located below a position from the source P+ region to a drift region and an ending point located below a position from the drift region to an isolation region.

5. The SOI power device with the introduced fixed charges according to claim 4, wherein the range of the first charge layer starts from a position below the source P+ region to a position below the N-buffer, and the ending point of the first charge layer at least reaches a position below the drain P+ region.

6. The SOI power device with the introduced fixed charges according to claim 1, wherein the first charge layer and the second charge layer are formed of a dielectric material, and positive ions are injected into an upper surface of the dielectric buried layer through ion implantation; and the positive ions are positive ions formed by group I or III element comprising positive cesium ions and positive boron ions.

7. The SOI power device with the introduced fixed charges according to claim 1, wherein the first charge layer and the second charge layer each have a surface charge density of greater than 1×10¹²/cm²; and the positive charges in the first charge layer and the second charge layer are distributed continuously and uniformly along the first charge layer and the second charge layer.

8. The SOI power device with the introduced fixed charges according to claim 7, wherein the first charge layer has a surface charge density of 1.3×10¹³/cm²; and the semiconductor active layer is made of silicon (Si), silicon carbide (SiC), gallium arsenide (GaAs), or gallium nitride (GaN), while the dielectric buried layer is made of a low dielectric constant material comprising silicon dioxide (SiO₂).

9. The SOI power device with the introduced fixed charges according to claim 7, wherein the second charge layer has a surface charge density of 8×10¹²/cm² to 9×10¹²/cm².

10. The SOI power device with the introduced fixed charges according to claim 7, wherein the first charge layer and the second charge layer each have a surface charge density of 5×10¹²/cm².
